(19) United States
(12) Patent Application Publication
(10) Pub. No.: US 2025/0254999 A1
(43) Pub. Date: Aug. 7, 2025

(54) ARRAY SUBSTRATES AND DISPLAY PANELS

(71) Applicant: Shenzhen China Star Optoelectronics Semiconductor Display Technology Co., Ltd., Shenzhen, Guangdong (CN)

(72) Inventors: Jinming SHI, Shenzhen, Guangdong (CN); Rui ZHAO, Shenzhen, Guangdong (CN); Weiji ZHANG, Shenzhen, Guangdong (CN)

(73) Assignee: Shenzhen China Star Optoelectronics Semiconductor Display Technology Co., Ltd., Shenzhen, Guangdong (CN)

(21) Appl. No.: 18/695,002

(22) PCT Filed: Feb. 7, 2024
(86) PCT No.: PCT/CN2024/076540

§ 371 Date: Mar. 25, 2024

(30) Foreign Application Priority Data
Jan. 30, 2024 (CN) 202410141958.6

(51) Int. Cl. H10D 86/60; H10D 30/01; H10D 30/67

(52) U.S. Cl. CPC H10D 86/60; H10D 30/0318; H10D 30/6728

(57) ABSTRACT

An array substrate and a display panel are disclosed. The array substrate includes a substrate, a first conductor portion located at a side of the substrate, a second conductor portion, and an active layer. The active layer includes a first doped portion, a second doped portion and a channel portion, the second doped portion is located at a side of the first doped portion away from the substrate, the channel portion is connected between the first doped portion and the second doped portion, the first conductor portion is contact with the first doped portion, and the second conductor portion is contact with the second doped portion.

### TECHNICAL FIELD

The present disclosure relates to display technologies, and in particular, to array substrates and display panels.

### BACKGROUND

With widespread application of display technologies, such as mobile phones, televisions, computers, virtual reality (VR) display devices, augmented reality (AR) display devices, or the like, the demand for display products with high pixel density which have a higher resolution is also increasing. Thin film transistor (TFT) is a switching element commonly used in an array substrate of a display panel. Doped portions in the active layer of the thin film transistor respectively in contact with the source and drain are located at two ends of the channel portion in the horizontal direction. The effective conductive channel length of the active layer is generally determined by the length of the channel between the source and the drain in the horizontal direction. It is difficult to reduce the size of the thin film transistor, resulting in that it is difficult to increase the pixel density (i.e., pixel per inch, PPI) of the display panel.

Therefore, an array substrate and a display panel are urgently required to solve the above technical problems.

### SUMMARY

The present disclosure provides an array substrate and a display panel, which can alleviate the technical problem that it is difficult to reduce the size of the thin film transistor of the current array substrate in the horizontal direction, resulting in that the improvement in the pixel density of the display panel is limited.

In order to solve the above problem, technical solutions provided by the present disclosure are as follows.

The present disclosure provides an array substrate including:
a substrate;
a first conductor portion located at a side of the substrate;
a second conductor portion located on a side of the first conductor portion away from the substrate;
an active layer including a first doped portion, a second doped portion and a channel portion, the second doped portion is located at a side of the first doped portion away from the substrate, and the channel portion is connected between the first doped portion and the second doped portion;
the first conductor portion is in contact with the first doped portion, and the second conductor portion is in contact with the second doped portion.

The present disclosure further provides a display panel including an array substrate, the array substrate includes:
a substrate;
a first conductor portion located at a side of the substrate;
a second conductor portion located at a side of the first conductor portion away from the substrate;
an active layer including a first doped portion, a second doped portion and a channel portion, the second doped portion is located at a side of the first doped portion away from the substrate, and the channel portion is connected between the first doped portion and the second doped portion;
the first conductor portion is in contact with the first doped portion, and the second conductor portion is in contact with the second doped portion.

### BRIEF DESCRIPTION OF THE DRAWINGS

FIG. 1 is a schematic structural diagram of a first structure of an array substrate provided by an embodiment of the present disclosure;

FIG. 2 is a schematic structural diagram of a second structure of an array substrate provided by an embodiment of the present disclosure;

FIG. 3 is a schematic structural diagram of a third structure of an array substrate provided by an embodiment of the present disclosure;

FIG. 4 is a schematic structural diagram of a fourth structure of an array substrate provided by an embodiment of the present disclosure;

FIG. 5 is a flow diagram of steps of a method of manufacturing an array substrate provided by an embodiment of the present disclosure;

FIG. 6a to FIG. 6h are schematic flow diagrams of a method of manufacturing an array substrate provided by an embodiment of the present disclosure;

FIG. 7 is a schematic diagram of a first structure of a display panel provided by an embodiment of the present disclosure;

FIG. 8 is a schematic diagram of a second structure of a display panel provided by an embodiment of the present disclosure.

### DETAILED DESCRIPTION

The present disclosure provides an array substrate and a display panel. In order to make the purpose, technical solutions and effects of the present disclosure clearer and more specific, the present disclosure will be further described in detail below with reference to the accompanying drawings and embodiments. It should be understood that specific embodiments described herein are only used to explain the present disclosure and are not intended to limit the present disclosure.

At present, the conductive channel length of the thin film transistor in the array substrate is determined by the length of the channel between the source and the drain in the horizontal direction, since it is difficult to reduce the size of the thin film transistor, resulting in the technical problem that the improvement of the pixel density of the display panel is limited.

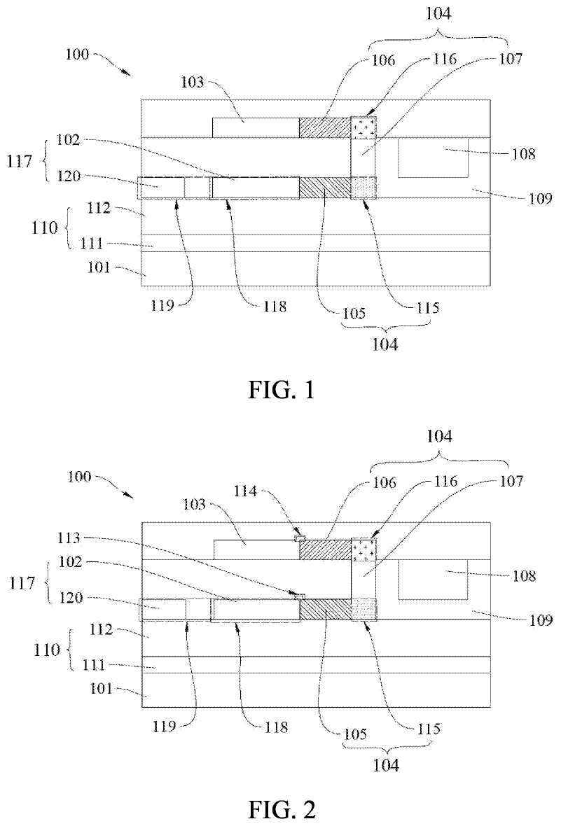

Referring to FIG. 1 to FIG. 4, an embodiment of the present disclosure provides an array substrate 100 including:
a substrate 101;
a first conductor portion 102 located at a side of the substrate 101;
a second conductor portion 103 located at a side of the first conductor portion 102 away from the substrate 101;
an active layer 104 including a first doped portion 105, a second doped portion 106 and a channel portion 107, the second doped portion 106 is located at a side of the first doped portion 105 away from the substrate 101, and the channel portion 107 is connected between the first doped portion 105 and the second doped portion 106;
the first conductor portion 102 is in contact with the first doped portion 105, and the second conductor portion 103 is in contact with the second doped portion 106.

In the embodiment of the present disclosure, the first doped portion 105 and the second doped portion 106 of the active layer 104 are disposed in different layers, and the channel portion 107 is connected between the first doped portion 105 and the second doped portion 106, thereby reducing the length of the channel portion 107 of the active layer 104 in the direction parallel to the substrate 101, and reducing the size of the thin film transistor in the array substrate 100, which are beneficial to increasing the pixel density of the display panel provided with the array substrate 100.

Technical solutions of the present disclosure will now be described with reference to specific embodiments.

Referring to FIG. 1 to FIG. 4, in this embodiment, the orthographic projection of the first doped portion 105 on the substrate 101 at least partially overlaps the orthographic projection of the second doped portion 106 on the substrate 101.

In this embodiment, the first conductor portion 102 is one of the source and the drain of the array substrate 100, and the second conductor portion 103 is another one of the source and the drain of the array substrate 100.

In some embodiments, the first conductor portion 102 is the source, and the second conductor portion 103 is the drain.

Referring to FIG. 1 to FIG. 4, in some embodiments, the orthographic projection of the first doped portion 105 on the substrate 101 and the orthogonal projection of the second doped portion 106 on the substrate 101 are at the same side of the orthographic projection of the channel portion 107 on the substrate 101. Alternatively, the orthographic projection of the end of the first doped portion 105 away from the channel portion 107 on the substrate 101 and the orthographic projection of the end of the second doped portion 106 away from the channel portion 107 on the substrate 101 are respectively at two sides of the orthographic projection of the channel portion 107 on the substrate 101.

Referring to FIG. 1 to FIG. 4, in some embodiments, the first conductor portion 102 is located on a side of the first doped portion 105 away from the first channel portion 107. The second conductor portion 103 is located on a side of the first doped portion 105 away from the first channel portion 107.

In some embodiments, the orthographic projection of the first conductor portion 102 on the substrate 101 and the orthographic projection of the second conductor portion 103 on the substrate 101 may be respectively at two sides of the orthographic projection of the channel portion 107 on the substrate 101. Alternatively, referring to FIG. 1 to FIG. 4, the orthographic projection of the first conductor portion 102 on the substrate 101 and the orthographic projection of the second conductor portion 103 on the substrate 101 are at the same side of the orthographic projection of the channel portion 107 on the substrate 101.

When the orthographic projection of the first conductor portion 102 on the substrate 101 and the orthographic projection of the second conductor portion 103 on the substrate 101 are at the same side of the orthographic projection of the channel portion 107 on the substrate 101, the orthographic projection of the first conductor portion 102 on the substrate 101 at least partially overlaps the orthographic projection of the second conductor portion 103 on the substrate 101.

Referring to FIG. 1 to FIG. 4, in some embodiments, the array substrate 100 further includes a gate 108, the gate 108 is located between the first conductor portion 102 and the second conductor portion 103.

In some embodiments, the gate 108 is located at a side of the channel portion 107 away from the first doped portion 105. That is, the orthographic projection of the gate 108 on the substrate 101 and the orthogonal projection of the first conductor portion 102 on the substrate 101 are respectively at two sides of the orthographic projection of the channel portion 107 on the substrate 101.

Alternatively, the gate 108 is located at a side of the channel portion 107 away from the second doped portion 106. That is, the orthographic projection of the gate 108 on the substrate 101 and the orthographic projection of the second conductor portion 103 on the substrate 101 are respectively at two sides of the orthographic projection of the channel portion 107 on the substrate 101.

Alternatively, referring to FIG. 1 to FIG. 2, when the orthographic projection of the first conductor portion 102 on the substrate 101 and the orthographic projection of the second conductor portion 103 on the substrate 101 are at the same side of the orthographic projection of the channel portion 107 on the substrate 101, the gate 108 is located at the side of the channel portion 107 away from the first doped portion 105, and the gate 108 is located at the side of the channel portion 107 away from the second doped portion 106.

The first conductor portion 102, the second conductor portion 103, the active layer 104 and the gate 108 constitute the thin film transistor of the array substrate 100. Compared with a thin film transistor in which the channel portion 107 extends in a direction parallel to the substrate 101, in a case where the orthographic projection of the first conductor portion 102 on the substrate 101 and the orthographic projection of the second conductor portion 103 on the substrate 101 are at the same side of the orthographic projection of the channel portion on the substrate 101, the gate 108 is located at the side of the channel portion 107 away from the first doped portion 105, and the gate 108 is located at the side of the channel portion 107 away from the second doped portion 106, the width of the thin film transistor in the direction parallel to the substrate 101 can be reduced by 3 microns to 4 microns, which is beneficial for improving the pixel density of the display panel applying the array substrate 100.

In some embodiments, when the gate 108 is located at the side of the channel portion 107 away from the second doped portion 106, the second conductor portion 103 and the gate 108 can be formed in the same process, and the thickness of the second conductor portion 103 is equal to the thickness of the gate 108, which are beneficial to simplifying the manufacturing process and reducing the manufacturing cost of the array substrate 100. It can be understood that when the ratio of the thickness of the second conductor portion 103 to the thickness of the gate 108 is in the range of 95:100 to 105:100, the thickness of the second conductor portion 103 and the thickness of the gate 108 can be regarded as the same. The thickness of the second conductor portion 103 is greater than the thickness of the first conductor in portion 102, and the thickness of the gate 108 is greater than the thickness of the first conductor portion 102.

In some embodiments, in a case where the gate 108 is located at the side of the channel portion 107 away from the first doped portion 105, and the gate 108 is located at the side of the channel portion 107 away from the second doped portion, the thickness of the gate 108 is greater than or equal to 400 nanometers, and the thickness of the gate 108 is less than or equal to 600 nanometers. For example, the thickness of the gate 108 can be 420 nanometers, 450 nanometers, 480 nanometers, 500 nanometers, 520 nanometers, 550 nanometers, 580 nanometers, and the like.

Referring to FIG. 1 to FIG. 4, in some embodiments, the array substrate 100 further includes a gate insulating layer 109 located between the first conductor portion 102 and the second conductor portion 103. The thickness of the gate insulating layer 109 is greater than or equal to 200 nanometers, and the thickness of the gate insulating layer 109 is less than or equal to 500 nanometers. For example, the thickness of the gate insulating layer 109 can be 220 nanometers, 240 nanometers, 250 nanometers, 260 nanometers, 280 nanometers, 300 nanometers, 320 nanometers., 340 nanometers, 350 nanometers, 360 nanometers, 380 nanometers, 400 nanometers, 420 nanometers, 440 nanometers, 450 nanometers, 460 nanometers, 480 nanometers, and the like.

In some embodiments, the material of the gate insulating layer 109 may be selected from silicon oxide (for example, silicon dioxide, and the like).

In some embodiments, when the gate 108 is located at the side of the channel portion 107 away from the second conductor portion 103, the gate insulating layer 109 includes a first opening, the gate 108 is located in the first opening, and the depth of the first opening is less than or equal to the thickness of the gate insulating layer 109.

In some embodiments, in a case where the orthographic projection of the first conductor portion 102 on the substrate 101 and the orthographic projection of the second conductor portion 103 on the substrate 101 are at the same side of the orthographic projection of the channel portion on the substrate 101, the gate 108 is located at the side of the channel portion 107 away from the first doped portion 105, and the gate 108 is located at the side of the channel portion 107 away from the second doped portion 106, the first opening may penetrate the gate insulating layer 109, and the thickness of the gate 108 may be greater than the depth of the first opening.

Referring to FIG. 1 to FIG. 4, in some embodiments, the array substrate 100 further includes a buffer layer 110 located between the substrate 101 and the first conductor portion 102. When the thickness of the gate 108 is greater than the depth of the first opening, the buffer layer 110 includes a second opening, the first opening is in communication with the first opening, and the gate 108 is located in the first opening and the second opening.

In some embodiments, the material of the buffer layer 110 may be selected from silicon oxide and/or silicon nitride.

Referring to FIG. 1 to FIG. 4, in some embodiments, the buffer layer 110 includes a first buffer sub-layer 111 and a second buffer sub-layer 112. The second buffer sub-layer 112 is located at the side of the first buffer sub-layer 111 away from the substrate 101. The material of the first buffer sub-layer 111 may be selected from silicon nitride. The thickness of the first buffer sub-layer 111 is greater than or equal to 30 nanometers, and the thickness of the first buffer sub-layer 111 is less than or equal to 70 nanometers. For example, the thickness of the first buffer sub-layer 111 can be 35 nanometers, 40 nanometers, 45 nanometers, 50 nanometers, 55 nanometers, 60 nanometers, 65 nanometers, and the like.

The material of the second buffer sub-layer 112 may be selected from silicon oxide. The thickness of the second buffer sub-layer 112 may be greater than or equal to 200 nanometers, and the thickness of the second buffer sub-layer 112 may be less than or equal to 400 nanometers. For example, the thickness of the second buffer sub-layer 112 can be 220 nanometers, 250 nanometers, 280 nanometers, 300 nanometers, 320 nanometers, 350 nanometers, 380 nanometers, and the like.

In some embodiments, the orthographic projection of the gate 108 on the substrate 101 at least partially overlaps the orthographic projection of the first conductor portion 102 on the substrate 101. That is, the orthographic projection of the gate 108 on the substrate 101 and the orthographic projection of the first conductor portion 102 on the substrate 101 are at the same side of the orthographic projection of the channel portion 107 on the substrate 101.

Alternatively, the orthographic projection of the gate 108 on the substrate 101 at least partially overlaps the orthographic projection of the second conductor portion 103 on the substrate 101. That is, the orthographic projection of the gate 108 on the substrate 101 and the orthographic projection of the second conductor portion 103 on the substrate 101 are located at the same side of the orthographic projection of the channel portion 107 on the substrate 101.

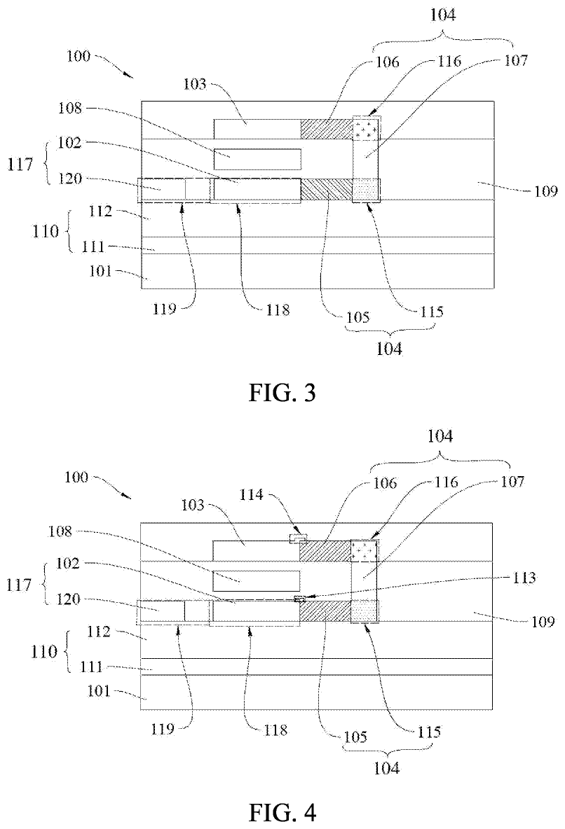

Alternatively, referring to FIG. 3 to FIG. 4, when the orthographic projection of the first conductor portion 102 on the substrate 101 and the orthographic projection of the second conductor portion 103 on the substrate 101 are located at the side of the orthographic projection of the channel portion on the substrate 101, the orthographic projection of the gate 108 on the substrate 101 at least partially overlaps the orthographic projection of the first conductor portion 102 on the substrate 101, and the orthographic projection of the gate 108 on the substrate 101 at least partially overlaps the orthographic projection of the second conductor portion 103 on the substrate 101.

Compared with the thin film transistor in which the channel portion 107 extends in a direction parallel to the substrate 101, in a case where the orthographic projection of the first conductor portion 102 on the substrate 101 and the orthographic projection of the second conductor portion 103 on the substrate 101 are at the same side of the orthographic projection of the channel portion on the substrate 101, the orthographic projection of the gate 108 on the substrate 101 is at least partially overlapped with the orthographic projection of the first conductor portion 102 on the substrate 101, and the orthographic projection of the gate 108 on the substrate 101 is at least partially overlapped with the orthographic projection of the second conductor portion 103 on the substrate 101, it is conducive to further reducing the size of the thin film transistor, and the width of the thin film transistor in the direction parallel to the substrate 101 can be reduced by 9 microns to 10 microns, which is beneficial to further improving the pixel density of the display panel applying the array substrate 100.

In some embodiments, in a case where the orthographic projection of the gate 108 on the substrate 101 is at least partially overlapped with the orthographic projection of the first conductor portion 102 on the substrate 101, and the orthographic projection of the gate 108 on the substrate 101 is at least partially overlapped with the orthographic projection of the second conductor portion 103 on the substrate 101, the thickness of the gate 108 is greater than or equal to 100 nanometers, and the thickness of the gate 108 is less than or equal to 200 nanometers. For example, the thickness of the gate 108 can be 120 nanometers, 140 nanometers, 150 nanometers, 160 nanometers, 180 nanometers, 190 nanometers, and the like.

In some embodiments, in a case where the orthographic projection of the gate 108 on the substrate 101 is at least partially overlapped with the orthographic projection of the first conductor portion 102 on the substrate 101, and the orthographic projection of the gate 108 on the substrate 101 is at least partially overlapped with the orthographic projection of the second conductor portion 103 on the substrate 101, the gate insulating layer 109 includes a first gate insulating sub-layer and a second gate insulating sub-layer. The first gate insulating sub-layer is located between the gate 108 and the first conductor portion 102, and the second gate insulating sub-layer is located between the gate 108 and the second conductor portion 103.

Referring to FIG. 1 to FIG. 4, in some embodiments, the active layer 104 further includes a third doped portion 115 located between the first doped portion 105 and the channel portion 107. The first doped portion 105 and the third doped portion 115 have a first doped element, and the concentration of the first doped element in the first doped portion 105 is greater than the concentration of the first doped element in the third doped portion 115.

In some embodiments, the materials of the first doped portion 105 and the third doped portion 115 are polysilicon with the first doped element. The first doped element may be selected from N-type doped elements, such as phosphorus element. The first doped portion 105 and the third doped portion 115 can be formed by blue laser annealing technology. In this process, the amorphous silicon becomes the polysilicon, the N-type doped element in the first doped portion 105 diffuses into the third doped portion 115, thereby forming the first doped portion 105 and the third doped portion 115 with different concentrations of doped element. Therefore, while omitting the step of forming the doped portion by ion implantation, it is beneficial to reducing the gradient of fringe field of the first conductor portion 102, reducing the generation of leakage current and avoiding the hot carrier effect, and addressing the tail-hanging problem of the off-state current of the thin film transistor in the array substrate 100.

Referring to FIG. 1 to FIG. 4, in some embodiments, the active layer 104 further includes a fourth doped portion 116 located between the second doped portion 106 and the channel portion 107. The second doped portion 106 and the fourth doped portion 116 have a second doped element, and the concentration of the second doped element in the second doped portion 106 is greater than the concentration of the second doped element in the fourth doped portion 116.

In some embodiments, the materials of the second doped portion 106 and the fourth doped portion 116 are polysilicon with the second doped element. The second doped element may be selected from N-type doped elements, such as phosphorus element. The second doped portion 106 and the fourth doped portion 116 can be formed by blue laser annealing technology. In this process, the amorphous silicon becomes the polysilicon, the N-type doped element in the second doped portion 106 diffuses to the fourth doped portion 116, thereby forming the second doped portion 106 and the fourth doped portion 116 with different concentrations of doped element. Therefore, while omitting the step of forming the doped portion by ion implantation, it is beneficial to reducing the gradient of fringe field of the second conductor portion 103, reducing the generation of leakage current and avoiding the hot carrier effect, and addressing the tail-hanging problem of the off-state current of the thin film transistor in the array substrate 100.

In some embodiments, the first doped portion 105 and the second doped portion 106 may be formed simultaneously.

In some embodiments, the material of the channel portion 107 may be undoped polysilicon, for example, undoped low-temperature polysilicon. The channel portion 107 may be formed by blue laser annealing technology. The channel portion 107, the first doped portion 105 and the second doped portion 106 may be formed simultaneously. The channel portion 107 is directly connected between the third doped portion 115 and the fourth doped portion 116.

In some embodiments, the gate insulating layer 109 includes a through hole, and the channel portion 107 is located in the through hole and connects the first doped portion 105 and the second doped portion 106.

Referring to FIG. 1 and FIG. 3, in some embodiments, the first doped portion 105 and the first conductor portion 102 are disposed in the same layer. The end surface of the first doped portion 105 close to the first conductor portion 102 is in contact with the end surface of the first conductor portion 102 close to the first doped portion 105.

Referring to FIG. 2 and FIG. 4, in some embodiments, the first doped portion 105 includes a first overlapping sub-portion 113, the firs overlapping sub-portion 113 is in contact with the first conductor portion 102, and the first overlapping sub-portion 113 is located at a side of the first conductor portion 102 away from the substrate 101. The first doped portion 105 may only include the first overlapping sub-portion 113, and the side of the first overlapping sub-portion 113 close to the substrate 101 is in contact with the first conductor portion 102. Alternatively, the first doped portion 105 further includes a first non-overlapping sub-portion, the first non-overlapping sub-portion and the first overlapping sub-portion 113 constitute the first doped portion 105, and the first non-overlapping sub-portion and the first conductor portion 102 are disposed in the same layer.

Referring to FIG. 1 to FIG. 4, in some embodiments, the array substrate 100 includes a first conductor layer 117, the first conductor portion is located in the first conductor layer 117. The array substrate 100 includes a first region 118 and the second region 119, the first region 118 is located at the side of the second region 119 close to the first doped portion 105. The first conductor layer 117 located in the second region 119 includes at least two stacked metal layers, and the number of metal layers of the first conductor layer 117 in the first region 118 is less than the number of metal layers of the first conductor layer 117 in the second region 119.

In some embodiments, the metal layers of the first conductor layer 117 in the second region 119 may include Mo, Ti, Cu, Al, ITO and other materials. For example, the first conductor layer 117 in the second region 119 may be composed of three metal layers formed by Mo, Ti, and Cu respectively, or, the first conductor layer 117 in the second region 119 can be composed of three metal layers formed by Mo, Al and Mo respectively.

The metal layer of the first conductor layer 117 in the first region 118 may include Mo, Ti, ITO and other materials. Compared with the first conductor layer 117 in the second region 119, the metal layer of the first conductor layer 117 in the first region 118 reduces a part of the metal materials such as Cu and Al. For example, the first conductor layer 117 in the first region 118 may be composed of two metal layers formed by Mo and Ti respectively, or, the first conductor layer 117 in the first region 118 may be composed of one or two metal layers formed by Mo.

When the first doped portion 105, the second doped portion 106 and the channel portion 107 are formed by blue laser annealing technology, the blue laser causes damage to metal materials such as Cu and Al. Therefore, by removing the metal layer formed of metal materials, such as Cu, Al of the first conductor layer 117 in the first region 118 closer to the first doped portion 105, it is beneficial to improving the product quality of the thin film transistor of the array substrate 100.

In some embodiments, the width of the orthographic projection of the first region 118 on the substrate is greater than or equal to 30 microns, and the width of the orthographic projection of the first region 118 on the substrate is less than or equal to 50 microns. For example, the width of the orthographic projection of the first region 118 on the substrate 101 may be 32 microns, 35 microns, 38 microns, 40 microns, 42 microns, 45 microns, 48 microns, and the like. Through the arrangement of the first region 118, the metal layer formed of metal materials, such as Cu, Al of the first conductor layer 117 closer to the first doped portion 105 is removed, which is beneficial to improving the product quality of the thin film transistor of the array substrate 100.

In some embodiments, the first conductor portion 102 is located at least partially in the first region 118.

In some embodiments, when the first doped portion 105 includes the first overlapping sub-portion 113, the first conductor portion 102 includes a first contacting sub-portion in contact with the first overlapping sub-portion 113, the orthographic projection of the first overlapping sub-portion 113 on the substrate 101 coincides with the orthographic projection of the first contacting sub-portion on the substrate 101. The first contacting sub-portion is located in the first region 118.

In some embodiments, the width of the orthographic projection of the first conductor portion 102 on the substrate 101 is greater than or equal to 5 microns, and the width of the orthographic projection of the first conductor portion 102 on the substrate 101 is less than or equal to 6 microns. For example, the width of the orthographic projection of the first conductor portion 102 on the substrate 101 can be 5.2 microns, 5.4 microns, 5.5 microns, 5.6 microns, 5.8 microns, and the like.

In some embodiments, the width of the orthographic projection of the first doped portion 105 on the substrate 101 is greater than or equal to 2 microns, and the width of the orthographic projection of the first conductor portion 102 on the substrate 101 is less than or equal to 3 microns. for example, the width of the orthographic projection of the first conductor portion 102 on the substrate 101 can be 2.2 microns, 2.4 microns, 2.5 microns, 2.6 microns, 2.8 microns, and the like.

In some embodiments, the sum of the widths of the orthographic projection of the first conductor portion 102 on the substrate 101 and the orthographic projection of the first doped portion 105 on the substrate 101 is greater than or equal to 7 microns, and the sum of the widths of the orthographic projection of the first conductor portion 102 on the substrate 101 and the orthographic projection of the first doped portion 105 on the substrate 101 is less than or equal to 9 microns. For example, the sum of the widths of the orthographic projection of the first conductor portion 102 on the substrate 101 and the orthographic projection of the first doped portion 105 on the substrate 101 can be 7.2 microns, 7.4 microns, 7.5 microns, 7.6 microns, 7.8 microns, 8 microns, 8.2 microns, 8.4 microns, 8.5 microns, 8.6 microns, 8.8 microns, and the like.

In some embodiments, the thickness of the first conductor portion 102 is greater than or equal to 50 nanometers, and the thickness of the first conductor portion 102 is less than or equal to 100 nanometers. For example, the thickness of the first conductor portion 102 can be 55 nanometers, 60 nanometers, 65 nanometers, 70 nanometers, 75 nanometers, 80 nanometers, 85 nanometers, 90 nanometers, 95 nanometers, and the like.

Referring to FIG. 1 to FIG. 4, in some embodiments, the array substrate 100 further includes a first wiring portion 120 disposed in the same layer as the first conductor portion 102. The material of the first wiring portion 120 and the material of the first conductor portion 102 are same, and the first wiring portion 120 and the first conductor portion 102 may be formed in the same manufacturing process. The thickness of the first wiring portion 120 is the same as the thickness of the first conductor portion 102. It can be understood that when the ratio of the thickness of the first conductor portion 102 to the thickness of the first wiring portion 120 is in the range of 95:100 to 105:100, the thickness of the first conductor portion 102 and the thickness of the first wiring portion 120 can be regarded as the same.

In some embodiments, the thickness of the first doped portion 105 is greater than or equal to 20 nanometers, and the thickness of the first doped portion 105 is less than or equal to 50 nanometers. For example, the thickness of the first doped portion 105 can be 25 nanometers, 30 nanometers, 35 nanometers, 40 nanometers, 45 nanometers, and the like.

Referring to FIG. 1 and FIG. 3, in some embodiments, the second doped portion 106 and the second conductor portion 103 are disposed in the same layer. The end surface of the second doped portion 106 close to the second conductor portion 103 is in contact with the end surface of the second conductor portion 103 close to the second doped portion 106.

Referring to FIG. 2 and FIG. 4, in some embodiments, the second conductor portion 103 includes a second overlapping sub-portion 114, the second overlapping sub-portion 114 is in contact with the second doped portion 106, and the second overlapping sub-portion 114 is located on the side of the second doped portion 106 away from the substrate 101. The second conductor portion 103 further includes a second non-overlapping sub-portion, the second non-overlapping sub-portion and the second overlapping sub-portion 114 constitute the second conductor portion 103, and the non-overlapping sub-portion and the second doped portion 106 are disposed in the same layer.

In some embodiments, the array substrate includes a second conductor layer, and the second conductor portion 103 is located in the second conductor layer. The second conductor layer may include at least two stacked metal layers. The metal layers of the second conductor layer may include Mo, Ti, Cu, Al, ITO and other materials. For example, the second conductor layer may be composed of three metal layers formed of Mo, Ti, and Cu respectively, or the second conductor layer may be composed of three metal layers formed of Mo, Al, and Mo respectively.

The second conductor layer is formed after the second doped portion 106 is formed, that is, the second conductor portion 103 is formed after treatment of blue laser annealing technology. Therefore, the second conductor layer does not need to be provided with a region in which a part of the metal materials, such as Cu and Al, is reduced.

In some embodiments, the second doped portion 106 includes a second contacting sub-portion, the second contacting sub-portion is in contact with the second overlapping sub-portion 114, and the orthographic projection of the second contacting sub-portion on the substrate 101 coincides with the orthographic projection of the second overlapping sub-portion 114 on the substrate 101. The second doped portion 106 may be only provided with the second contacting sub-portion. Alternatively, the second doped portion 106 further includes a second non-contacting sub-portion, and the orthographic projection of the second non-contacting sub-portion on the substrate 101 is located outside the orthographic projection of the second overlapping sub-portion 114 on the substrate 101.

In some embodiments, the thickness of the second conductor portion 103 is greater than or equal to 400 nanometers, and the thickness of the second conductor portion 103 is less than or equal to 600 nanometers. For example, the thickness of the second conductor portion 103 can be 420 nanometers, 450 nanometers, 480 nanometers, 500 nanometers, 520 nanometers, 550 nanometers, 580 nanometers, and the like.

In some embodiments, the array substrate 100 further includes a second wiring portion disposed in the same layer as the second conductor portion 103, the material of the second wiring portion is the same as the material of the second conductor portion 103, and the second wiring portion and the second conductor portion 103 can be formed in the same manufacturing process. The thickness of the second wiring portion is the same as the thickness of the second conductor portion 103. It can be understood that when the ratio of the thickness of the second conductor portion 103 to the thickness of the second wiring portion is in the range of 95:100 to 105:100, the thickness of the second conductor portion 103 and the thickness of the second wiring portion can be regarded as the same.

In some embodiments, the thickness of the second doped portion 106 is greater than or equal to 20 nanometers, and the thickness of the second doped portion 106 is less than or equal to 50 nanometers. For example, the thickness of the second doped portion 106 can be 25 nanometers, 30 nanometers, 35 nanometers, 40 nanometers, 45 nanometers, and the like.

In some embodiments, the substrate 101 may be a rigid substrate, such as a glass substrate; or, the substrate 101 may be a flexible substrate, for example, the substrate 101 may be a substrate made of polyimide. When the substrate 101 is a flexible substrate, the substrate 101 may be formed of a plurality of layers of sub-substrates made of the same material, such as polyimide, and adjacent sub-substrates are bonded by an adhesive sub-layer.

In the array substrate 100 provided by the embodiments, the first doped portion 105 and the second doped portion 106 of the active layer 104 are disposed in different layers, and the channel portion 107 is connected between the first doped portion 105 and the second doped portion 106, thereby reducing the length of the channel portion 107 of the active layer 104 in the direction parallel to the substrate 101, and reducing the size of the thin film transistor in the array substrate 100, which are beneficial to improving the pixel density of the display panel provided with the array substrate 100.

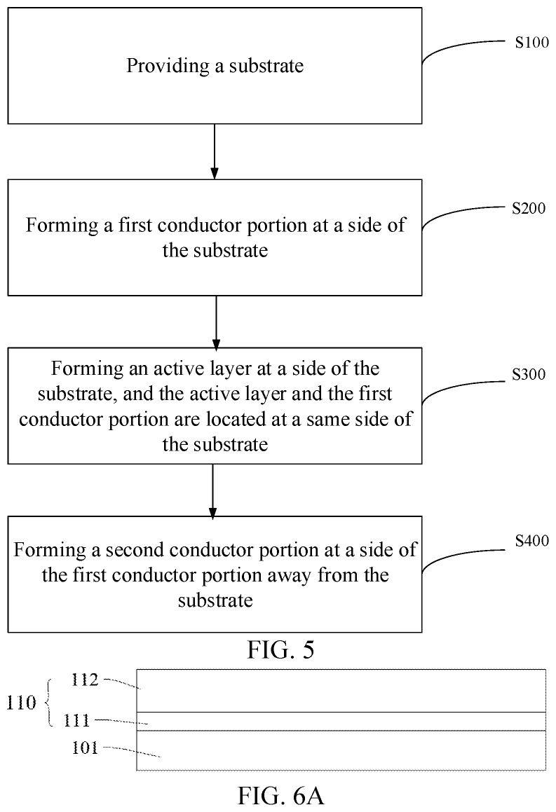

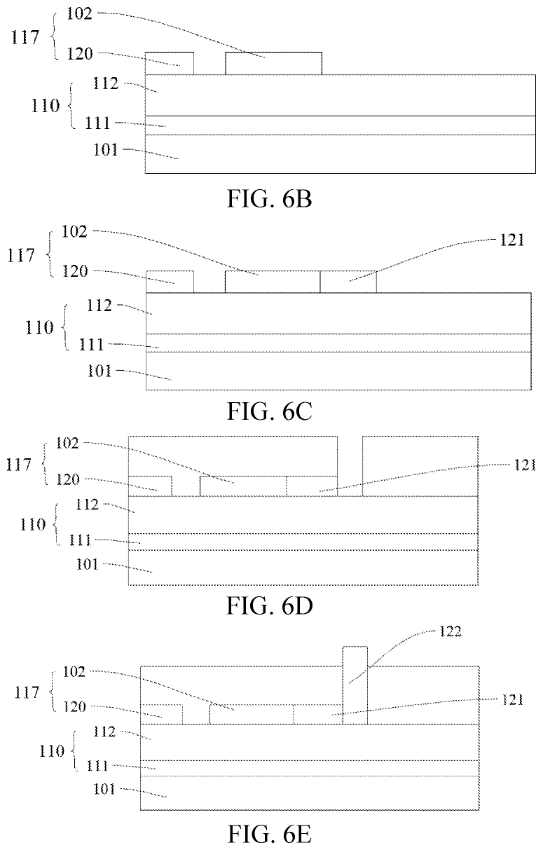

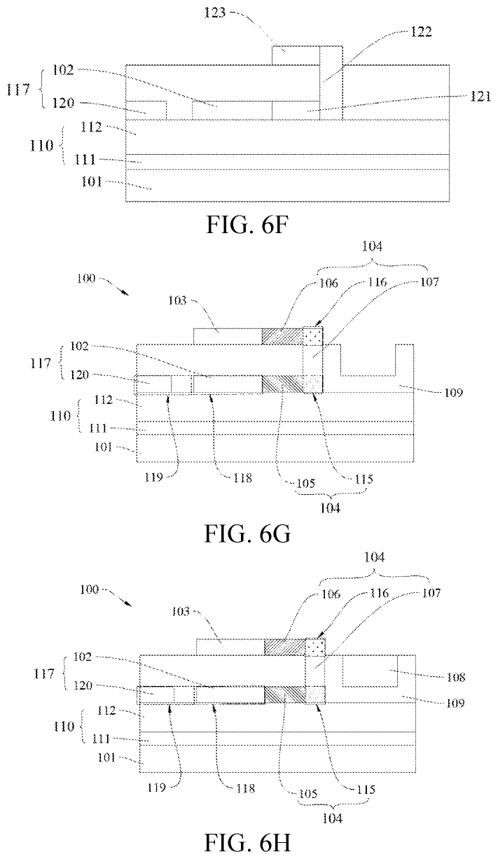

Referring to FIG. 5 and FIG. 6a to FIG. 6h, an embodiment of the present disclosure further provides a method of manufacturing an array substrate including:
S100, providing a substrate 101.
S200, forming a first conductor portion 102 at a side of the substrate 101.
S300, forming an active layer 104 at a side of the substrate 101, and the active layer 104 and the first conductor portion 102 are located at the same side of the substrate 101.
S400, forming a second conductor portion 103 at a side of the first conductor portion 102 away from the substrate 101.

The active layer 104 includes a first doped portion 105, a second doped portion 106 and a channel portion 107. The second doped portion 106 is located at a side of the first doped portion 105 away from the substrate 101, the channel portion 107 is connected between the first doped portion 105 and the second doped portion 106. The first conductor portion 102 is in contact with the first doped portion 105, and the second conductor portion 103 is in contact with the second doped portion 106.

Referring to FIG. 6a, in some embodiments, after step S100 and before step S200, the method further includes:
S500, forming a buffer layer 110 on a side of the substrate 101.

The buffer layer 110 is located between the first conductor portion 102 and the substrate 101, that is, the first conductor portion 102 is formed at a side of the buffer layer 110 away from the substrate 101.

In some embodiments, step S500 includes:
S510, forming a first buffer sub-layer 111 on a side of the substrate 101.
S520, forming a second buffer sub-layer 112 on a side of the first buffer sub-layer 111 away from the substrate 101.

The thicknesses and materials of the first buffer sub-layer 111 and the second buffer sub-layer 112 have been described in detail in the array substrate described above, and will not be described again herein.

Referring to FIG. 6b, in some embodiments, step S200 includes:
S210, forming a first conductor material layer at a side of the substrate 101.

In some embodiments, the first conductor material layer may be formed by stacking at least two metal material layers.

S220, patterning the first conductor material layer to form a first conductor layer 117, and the first conductor layer 117 includes the first conductor portion 102.

In some embodiments, the array substrate includes a first region 118 and a second region 119. The first region 118 is located at a side of the second region 119 close to the first doped portion 105. The first conductor layer 117 in the second region 119 includes at least two stacked metal layers, and when the number of metal layers of the first conductor layer 117 in the first region 118 is less than the number of metal layers of the first conductor layer 117 in the second region 119, step S220 includes:
S221, forming a first photoresist layer on a side of the first conductor material layer away from the substrate 101.
S222, patterning the first photoresist layer to form a first photoresist region, a second photoresist region and a third photoresist region.

The photoresist in the first photoresist region is removed, and the thickness of the photoresist in the second photoresist region is less than the thickness of the photoresist in the third photoresist region.

S223, removing the first conductor material layer in a region corresponding to the first photoresist region.

S224, removing the photoresist in the second photoresist region.

S225, removing at least one metal material layer in the first conductor material layer in a region corresponding to the second photoresist region to form the first conductor layer 117 in the first region 118.

In some embodiments, the metal material layer of the first conductor layer 117 removed in the first region 118 may be a Cu or Al material layer.

S226, removing the photoresist in the third photoresist region to form the first conductor layer 117 in the second region.

The first conductor portion 102 is located at least partially in the first region 118.

The structure, thickness and material of the first conductor portion 102 have been described in detail in the aforementioned array substrate, and will not be described again herein.

Referring to FIG. 6c to FIG. 6f, in some embodiments, step S300 includes:
S310, forming a first doped material layer 121 on an end of the first conductor portion 102 in a direction parallel to the substrate 101.
S320, forming a gate insulating layer 109 at the side of the first conductor portion 102 away from the substrate 101, and the gate insulating layer 109 includes a through hole.
S330, forming a channel material layer 122 in the through hole, and the channel material layer 122 is connected to an end of the first doped material layer 121.
S340, forming a second doped material layer 123 at a side of the insulating material layer away from the substrate 101, and the channel material layer 122 is connected to an end of the second doped material layer 123.
S350, performing blue laser annealing technology treatment on the first doped material layer 121, the second doped material layer 123, and the channel material layer 122 to form the first doped portion 105, the second doped portion 106, the third doped portion 115, the fourth doped portion 116 and the channel portion 107.

Through the treatment of blue laser annealing technology, the first doped element in the first doped material layer 121 diffuses to the channel material layer 122 connected to the end of the first doped material layer 121, and the second doped element in the second doped material layer 123 diffuses to the channel material layer 122 connected to the end of the second doped material layer 123. Therefore, one end of the first channel material layer 122 connected to the first doped material layer 121 at least partially becomes the third doped portion 115, and one end of the second channel material layer 122 connected to the second doped material layer 123 at least partially becomes the fourth doped portion 116.

In some embodiments, the thickness of the channel material layer 122 is greater than or equal to 200 nanometers, and the thickness of the channel material layer 122 is less than or equal to 500 nanometers. For example, the thickness of the channel material layer 122 can be 220 nanometers, 250 nanometers, 280 nanometers, 300 nanometers, 320 nanometers, 350 nanometers, 380 nanometers, 400 nanometers, 420 nanometers, 450 nanometers, 480 nanometers, and the like.

In some embodiments, the thickness of the channel material layer 122 is greater than or equal to the thickness of the gate insulating layer 109.

In some embodiments, the thickness of the channel material layer 122 is equal to the sum of the thickness of the gate insulating layer 109 and the thickness of the second doped material layer 123.

The structures and materials of the first doped portion 105, the second doped portion 106, the third doped portion 115, the fourth doped portion 116, and the channel portion 107 have been explained in the aforementioned array substrate, and will not be described again herein.

Referring to FIG. 6g to FIG. 6h, in some embodiments, the method of manufacturing the array substrate further includes:
S600, forming a gate 108 at a side of the channel portion 107 away from the first conductor portion 102 and/or the second conductor portion 103.

In some embodiments, step S600 is performed after step S300 and before step S400, and step S600 includes:
S610, forming a first opening in the gate insulating layer 109, and the first opening is located at a side of the channel portion 107 away from the first conductor portion 102 and/or the second conductor portion 103.
S620, forming the gate 108 in the first opening.

In some embodiments, the thickness of the gate 108 is greater than the thickness of the gate insulating layer 109, and step S600 includes:
S630, forming a first opening in the gate insulating layer 109 and forming a second opening in the second buffer sub-layer 112, the first opening and the second opening are located at a side of the channel portion 107 away from the first conductor portion 102 and/or the second conductor portion 103, and the first opening is in communication with the second opening.
S640, forming the gate 108 in the first opening and the second opening.

In some embodiments, step S600 and step S320 are performed simultaneously. Specifically, step S320 includes:
S321, forming a first gate insulating sub-layer at a side of the first conductor portion 102 away from the substrate 101.
S322, forming a second gate insulating sub-layer at a side of the first gate insulating sub-layer away from the substrate 101.
S333, forming a through hole penetrating the first gate insulating sub-layer and the second gate insulating sub-layer.

After step S321 and before step S322, step S600 includes:
S650, forming the gate 108 at the side of the first gate insulating sub-layer away from the substrate 101.

The orthographic projection of the gate 108 on the substrate 101 at least partially overlaps the orthographic projection of the first conductor portion 102 on the substrate 101 and/or the orthographic projection of the second conductor portion 103 on the substrate 101.

The second gate insulating sub-layer covers the gate 108.

In the method of manufacturing an array substrate provided by the embodiments of the present disclosure, the first doped portion 105 and the second doped portion 106 of the active layer 104 are disposed in different layers, and the channel portion 107 is connected between the first doped portion 105 and the second doped portion 106, thereby reducing the length of the channel portion 107 of the active layer 104 in the direction parallel to the substrate 101, and reducing the size of the thin film transistor in the array substrate, which are beneficial to improving the pixel density of the display panel provided with the array substrate.

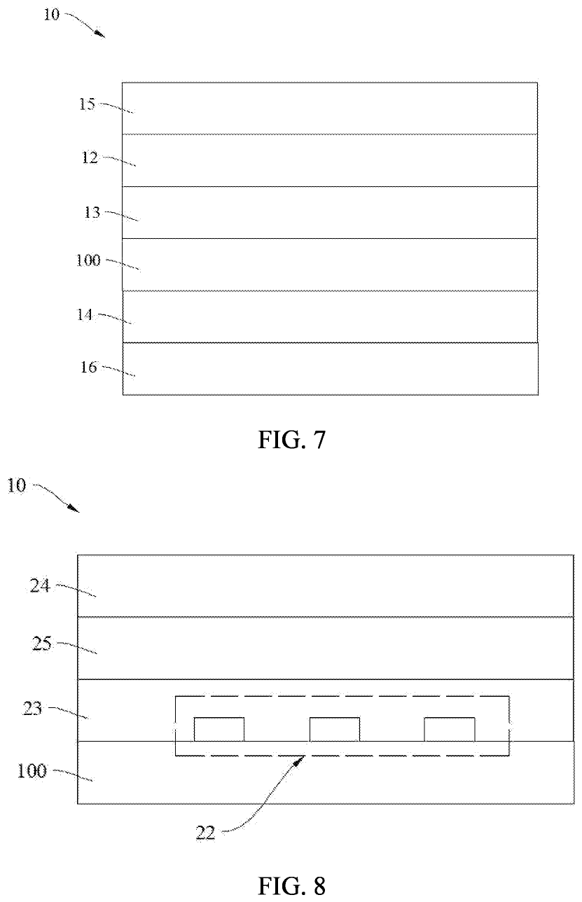

Referring to FIG. 7 and FIG. 8, an embodiment of the present disclosure further provides a display panel 10 including the array substrate 100 as described above.

For the specific structure of the array substrate 100, please refer to any one of the array substrates in the above embodiments and the accompanying drawings, and will not be described again herein.

In some embodiments, the display panel 10 may be a liquid crystal display panel or a self-light emitting display panel.

Referring to FIG. 7, when the display panel 10 is a liquid crystal display panel, the display panel 10 further includes a color filter substrate 12 disposed opposite to the array substrate 100, a liquid crystal layer 13 located between the color filter substrate 12 and the array substrate 100, a first polarizer layer 14 located on the side of the array substrate 100 away from the color filter substrate 12, and a second polarizer layer 15 located on the side of the color filter substrate 12 away from the array substrate 100. When the display panel 10 is a liquid crystal display panel, the display panel 10 further includes a backlight assembly 16, the backlight assembly 16 is located on a side of the first polarizer layer 14 away from the array substrate 100, or, the backlight assembly 16 is located on a side of the second polarizer layer 15 away from the color filter substrate 12.

Referring to FIG. 8, when the display panel 10 is a self-light emitting display panel, the display panel 10 further includes a light emitting device layer 22 located on a side of the array substrate 100 away from the substrate 101. The light emitting device layer 22 includes a plurality of light emitting devices, and the light emitting devices may include organic light-emitting diode (OLED) materials, or may include Micro LED or Mini LED, which are not specifically limited herein. When the display panel 10 is a self-light emitting display panel, the display panel 10 further includes an encapsulating layer 23 located on a side of the light emitting device layer 22 away from the array substrate 100. The encapsulating layer 23 may include a first inorganic encapsulating sub-layer, a first organic encapsulating sub-layer and a second inorganic encapsulating sub-layer. When the display panel 10 is a self-light emitting display panel, the display panel 10 further includes a cover plate layer 24 located on a side of the encapsulating layer 23 away from the array substrate 100. When the display panel 10 is a self-light emitting display panel, the display panel 10 further includes a polarizing layer 25 located between the encapsulating layer 23 and the cover plate layer 24.

The display panel 10 can be applied to display terminals such as mobile phones, tablets, televisions, computers, virtual reality display devices, and augmented reality display devices.

The embodiments of the present disclosure disclose an array substrate and a display panel. The array substrate includes a substrate, a first conductor portion located at a side of the substrate, a second conductor portion located at a side of the first conductor portion away from the substrate, and an active layer. The active layer includes a first doped portion, a second doped portion and channel portion, the second doped portion is located at a side of the first doped portion away from the substrate, the channel portion is connected between the first doped portion and the second doped portion, the first conductor portion is contact with the first doped portion, and the second conductor portion is contact with the second doped portion. In the present disclosure, the first doped portion and the second doped portion of the active layer are disposed in different layers, and the channel portion is connected between the first doped portion and the second doped portion, thereby reducing the length of the channel portion of the active layer in the direction parallel to the substrate, and reducing the size of the thin film transistor in the array substrate, which are beneficial to increasing the pixel density of the display panel provided with the array substrate.

It can be understood that, for those of ordinary skill in the art, equivalent replacements or changes can be made based on the technical solutions and inventive concepts of the present disclosure, and all such changes or replacements should fall within the protection scope of the appended claims of the present disclosure.

What is claimed is:

1. An array substrate comprising:
a substrate;
a first conductor portion located at a side of the substrate;
a second conductor portion located at a side of the first conductor portion away from the substrate;
an active layer comprising a first doped portion, a second doped portion and a channel portion, wherein the second doped portion is located at a side of the first doped portion away from the substrate, and the channel portion is connected between the first doped portion and the second doped portion;
wherein the first conductor portion is in contact with the first doped portion, and the second conductor portion is in contact with the second doped portion.

2. The array substrate according to claim 1, wherein an orthographic projection of the first doped portion on the substrate at least partially overlaps an orthographic projection of the second doped portion on the substrate, and an orthographic projection of the first conductor portion on the substrate at least partially overlaps an orthographic projection of the second conductor portion on the substrate.

3. The array substrate according to claim 2, wherein the array substrate further comprises a gate, the gate is located between the first conductor portion and the second conductor portion, the gate is located at a side of the channel portion away from the first doped portion, and the gate is located at a side of the channel portion away from the second doped portion.

4. The array substrate according to claim 3, wherein the gate is located at the side of the channel portion away from the second doped portion, and a thickness of the second conductor portion is the same as a thickness of the gate.

5. The array substrate according to claim 4, wherein the thickness of the gate is greater than or equal to 400 nanometers, and the thickness of the gate is less than or equal to 600 nanometers.

6. The array substrate according to claim 2, wherein the array substrate further comprises a gate, the gate is located between the first conductor portion and the second conductor portion, an orthographic projection of the gate on the substrate at least partially overlaps the orthographic projection of the first conductor portion on the substrate, and the orthographic projection of the gate on the substrate overlaps the orthographic projection of the second conductor portion on the substrate.

7. The array substrate according to claim 6, wherein a thickness of the gate is greater than or equal to 100 nanometers, and the thickness of the gate is less than or equal to 200 nanometers.

8. The array substrate according to claim 1, wherein the first doped portion and the first conductor portion are disposed in a same layer.

9. The array substrate according to claim 1, wherein the first doped portion comprises a first overlapping sub-portion, the first overlapping sub-portion is in contact with the first conductor portion, and the first overlapping sub-portion is located on a side of the first conductor portion away from the substrate.

10. The array substrate according to claim 1, wherein the array substrate comprises a first conductor layer, the first conductor portion is located in the first conductor layer, the array substrate comprises a first region and a second region, and the first region is located at a side of the second region close to the first doped portion; and
the first conductor layer in the second region comprises at least two stacked metal layers, and a number of metal layers of the first conductor layer in the first region is less than a number of metal layers of the first conductor layer in the second region.

11. The array substrate according to claim 10, wherein a width of an orthographic projection of the first region on the substrate is greater than or equal to 30 microns, and the width of the orthographic projection of the first region on the substrate is less than or equal to 50 microns.

12. The array substrate according to claim 1, wherein the second doped portion and the second conductor portion are disposed in a same layer.

13. The array substrate according to claim 1, wherein the second conductor portion comprises a second overlapping sub-portion, the second overlapping sub-portion is in contact with the second doped portion, and the second overlapping sub-portion is located on a side of the second doped portion away from the substrate.

14. The array substrate according to claim 1, wherein the active layer further comprises a third doped portion located between the first doped portion and the channel portion, the first doped portion and the third doped portion have a first doped element, and a concentration of the first doped element in the first doped portion is greater than a concentration of the first doped element in the third doped portion; and
the active layer further comprises a fourth doped portion located between the second doped portion and the channel portion, the second doped portion and the fourth doped portion have a second doped element, and a concentration of the second doped element in the second doped portion is greater than a concentration of the second doped element in the fourth doped portion.

15. The array substrate according to claim 1, wherein the first conductor portion is one of a source and a drain of the array substrate, and the second conductor portion is another one of the source and the drain of the array substrate.

16. A display panel comprising an array substrate, wherein the array substrate comprises:
a substrate;
a first conductor portion located at one side of the substrate;
a second conductor portion located at one side of the first conductor portion away from the substrate;
an active layer comprising a first doped portion, a second doped portion and a channel portion, wherein the second doped portion is located at a side of the first doped portion away from the substrate, and the channel portion is connected between the first doped portion and the second doped portion;
wherein the first conductor portion is in contact with the first doped portion, and the second conductor portion is in contact with the second doped portion.

17. The display panel according to claim 16, wherein an orthographic projection of the first doped portion on the substrate at least partially overlaps an orthographic projection of the second doped portion on the substrate, and an orthographic projection of the first conductor portion on the substrate at least partially overlaps an orthographic projection of the second conductor portion on the substrate.

18. The display panel according to claim 17, wherein the array substrate further comprises a gate, the gate is located between the first conductor portion and the second conductor portion, the gate is located at a side of the channel portion away from the first doped portion, and the gate is located at a side of the channel portion away from the second doped portion.

19. The display panel according to claim 17, wherein the array substrate further comprises a gate, the gate is located between the first conductor portion and the second conductor portion, an orthographic projection of the gate on the substrate at least partially overlaps the orthographic projection of the first conductor portion on the substrate, and the orthographic projection of the gate on the substrate overlaps the orthographic projection of the second conductor portion on the substrate.

20. The display panel according to claim 16, wherein the array substrate comprises a first conductor layer, the first conductor portion is located in the first conductor layer, the array substrate comprises a first region and a second region, and the first region is located at a side of the second region close to the first doped portion; and
the first conductor layer in the second region comprises at least two stacked metal layers, and a number of metal layers of the first conductor layer in the first region is less than a number of metal layers of the first conductor layer in the second region.
